(19) United States
(12) Patent Application Publication
(10) Pub. No.: US 2024/0394020 A1
(43) Pub. Date: Nov. 28, 2024

(54) SYSTEM AND METHOD FOR GENERATING A RANDOM NUMBER, AND CIRCUIT FOR COMMUNICATING AN ANALOG RANDOM SIGNAL

(71) Applicant: QUANTUM EMOTION CORP., Montréal (CA)

(72) Inventor: Bertrand REULET, Sherbrooke (CA)

(21) Appl. No.: 18/696,152

(22) PCT Filed: Sep. 28, 2022
(86) PCT No.: PCT/CA2022/051438

§ 371 Date: Mar. 27, 2024

Related U.S. Application Data
(60) Provisional application No. 63/249,734, filed on Sep. 29, 2021.

(51) Int. Cl. G06F 7/58; H03F 3/183

(52) U.S. Cl. CPC G06F 7/588; H03F 3/183

(57) ABSTRACT

There is described a system for generating at least one random number. The system generally has a circuit having a board, a quantum tunnelling barrier mounted to the board and generating an analog random signal, an audio amplifier mounted to the board and configured for amplifying the analog random signal within an audio frequency range, the audio frequency range including frequencies below 20 KHz, thereby generating an amplified analog random signal; a communication link communicatively coupled to the audio amplifier; and a computer being having a processor, a computer-readable memory and audio analog-to-digital converter in communication with the communication link, the computer-readable memory having stored thereon instructions that when executed by the processor perform the steps of: the audio analog-to-digital converter converting the amplified analog random signal into a digitized random signal; and the processor generating at least one random number based on the digitized random signal.

### FIELD

The improvements generally relate to random number generation and more particularly to random number generation using quantum tunneling barriers.

### BACKGROUND

Random numbers have found valuable applications in many fields such as cryptography, games of chance, scientific calculus and/or statistical studies. In these applications, the randomness of the generated random numbers is of great importance since their predictability can lead to unsecure communication, cheating and/or unreliable scientific results, for instance. Contrary to classical mechanics, quantum mechanics present features which are inherently random. For instance, International Patent Application published under no. WO 2015/168798 describes a random number generator involving a quantum tunnelling barrier across which charges (negatively-charged electrons or positively-charged holes) randomly tunnel to generate a low-level random electrical noise which can be used as a basis for the random number generation. Although existing random number generators are satisfactory to a certain degree, there remains room for improvement, especially in reducing pricing and bulkiness of these generators.

### SUMMARY

There is described a circuit having a quantum tunnelling barrier generating an analog random signal that can be used as a basis for random number generation. The circuit takes advantage of audio processing hardware, e.g., sound cards, generally found in computers or laptops. More specifically, it was found that by providing the circuit with an audio amplifier, i.e., a standard, mass-produced electronic component that is configured for amplifying analog signals carrying frequencies in an audio frequency range, the analog random signal produced by the quantum tunnelling barrier can be amplified in the audio frequency range to form an amplified analog random signal. By communicating the amplified analog random signal to the computer or laptop via a communication link, such as a USB cable, the audio processing hardware of the computer or laptop can digitize the amplified analog random signal and thereby provide random bits that can be used for random number generation. In some embodiments, it is envisaged that the circuit can be powered by the computer via the communication link, thereby allowing the circuit to have a reduced number of electronic components which can be beneficial in terms of both pricing and bulkiness.

In accordance with a first aspect of the present disclosure, there is provided a system for generating at least one random number, the system comprising: a circuit having a board, a quantum tunnelling barrier mounted to the board, the quantum tunnelling barrier having an insulator having two exterior opposite faces each in contact with a corresponding one of two conductors and allowing charges to randomly tunnel from one of the conductors to the other conductor across the insulator to form a current of tunneled charges passing through the insulator, the current of tunneled charges having an instantaneous level varying randomly due to quantum tunneling and forming an analog random signal, an audio amplifier mounted to the board and configured for amplifying the analog random signal within an audio frequency range, the audio frequency range including frequencies below 20 kHz, thereby generating an amplified analog random signal; a communication link communicatively coupled to the audio amplifier; and a computer being having a processor, a computer-readable memory and an audio analog-to-digital converter in communication with the communication link, the computer-readable memory having stored thereon instructions that when executed by the processor perform the steps of: the audio analog-to-digital converter converting the amplified analog random signal into a digitized random signal; and the processor generating at least one random number based on the digitized random signal.

Further in accordance with the first aspect of the present disclosure, the computer can for example have a voltage source applying a bias voltage between the two conductors of the quantum tunneling barrier via the communication link.

Still further in accordance with the first aspect of the present disclosure, the computer can for example have a voltage source powering the audio amplifier via the communication link.

Still further in accordance with the first aspect of the present disclosure, the communication link can for example have a connector connectable to a corresponding connector of the external computer, the connector being a USB-C connector.

Still further in accordance with the first aspect of the present disclosure, the USB-C connector can for example be operated in an audio accessory mode.

Still further in accordance with the first aspect of the present disclosure, the board of the circuit can for example be a printed circuit board.

Still further in accordance with the first aspect of the present disclosure, the system can for example further comprise a housing enclosing the circuit and the audio amplifier, the housing having a communication port to which the communication link is removably connected.

Still further in accordance with the first aspect of the present disclosure, the audio analog-to-digital converter can for example be part of a sound card of the computer.

Still further in accordance with the first aspect of the present disclosure, the circuit can for example be part of the computer.

In accordance with a second aspect of the present disclosure, there is provided a circuit for communicating an analog random signal, the circuit comprising: a board; a quantum tunnelling barrier mounted to the board, the quantum tunnelling barrier having an insulator having two exterior opposite faces each in contact with a corresponding one of two conductors and allowing charges to randomly tunnel from one of the conductors to the other conductor across the insulator to form a current of tunneled charges passing through the insulator, the current of tunneled charges having an instantaneous level varying randomly due to quantum tunneling and forming an analog random signal; an audio amplifier mounted to the board and configured for amplifying the instantaneous level of the analog random signal within an audio frequency range and generating an amplified analog random signal, the audio frequency range including frequencies below 20 KHz; and a communication link communicatively coupled to the audio amplifier and connectable to an external computer for communicating the amplified analog random signal thereto.

Further in accordance with the second aspect of the present disclosure, the audio amplifier can for example be configured to amplify at least 80% of the audio frequency range, preferably at least 90% of the audio frequency range and most preferably at least 95% of the audio frequency range.

Still further in accordance with the second aspect of the present disclosure, the circuit can for example further comprise a voltage source mounted to the board, the voltage source being configured for applying a bias voltage between the two conductors of the quantum tunneling barrier and for powering the audio amplifier.

Still further in accordance with the second aspect of the present disclosure, the circuit can for example further comprise an audio analog-to-digital converter mounted to the board, the audio analog-to-digital converter being configured for converting the amplified analog random signal into a digitized random signal.

Still further in accordance with the second aspect of the present disclosure, the communication link can for example have a connector connectable to a corresponding connector of the external computer, the connector being a USB-C connector.

Still further in accordance with the second aspect of the present disclosure, the USB-C connector can for example be operated in an audio accessory mode.

Still further in accordance with the second aspect of the present disclosure, the board can for example be a printed circuit board.

In accordance with a third aspect of the present disclosure, there is provided a method of generating at least one random number, the method comprising: generating a current of charges tunneling from a first one of two conductors to a second one of the two conductors across an insulator, the current of the tunneled charges having an instantaneous level varying randomly due to quantum tunneling and forming an analog random signal; using an audio amplifier, amplifying the instantaneous level of the analog random signal over an audio frequency range, the audio frequency range including frequencies below 20 KHz; using an audio analog-to-digital converter, converting the amplified analog random signal into a digitized random signal; and generating at least one random number based the digitized random signal.

Further in accordance with the third aspect of the present disclosure, the method can for example further comprise a communication link communicating said amplified analog random signal from the audio amplifier to the audio analog-to-digital converter.

Still further in accordance with the third aspect of the present disclosure, the method can for example further comprise applying a bias voltage across the two conductors via the communication link.

Still further in accordance with the third aspect of the present disclosure, the method can for example further comprise powering the audio amplifier via the communication link.

Many further features and combinations thereof concerning the present improvements will appear to those skilled in the art following a reading of the instant disclosure.

### DESCRIPTION OF THE FIGURES

In the figures,

FIG. 1 is a side elevation view of an example of a system for generating random numbers, showing a circuit being communicatively coupled to a personal computer via a communication link, in accordance with one or more embodiments;

FIG. 2 is a schematic view of an example of a computing device of the computer of FIG. 1, in accordance with one or more embodiments;

FIG. 3 is a schematic view of the system of FIG. 1, in accordance with one or more embodiments;

FIG. 4 is a graph showing amplification bands of an audio amplifier of the circuit of FIG. 1, in accordance with one or more embodiments;

FIG. 4A is a block diagram of the circuit of FIG. 1, in accordance with one or more embodiments;

FIG. 5 is a schematic view of pins of the communication link of FIG. 1, in accordance with one or more embodiments;

FIG. 6 is a schematic view of another example of a system for generating random numbers, showing a circuit having a voltage source, in accordance with one or more embodiments;

FIG. 7 is a schematic view of another example of a system for generating random numbers, showing a circuit having an audio analog-to-digital converter, in accordance with one or more embodiments; and

FIG. 8 is a flow chart of an example of a method of generating random numbers, in accordance with one or more embodiments.

### DETAILED DESCRIPTION

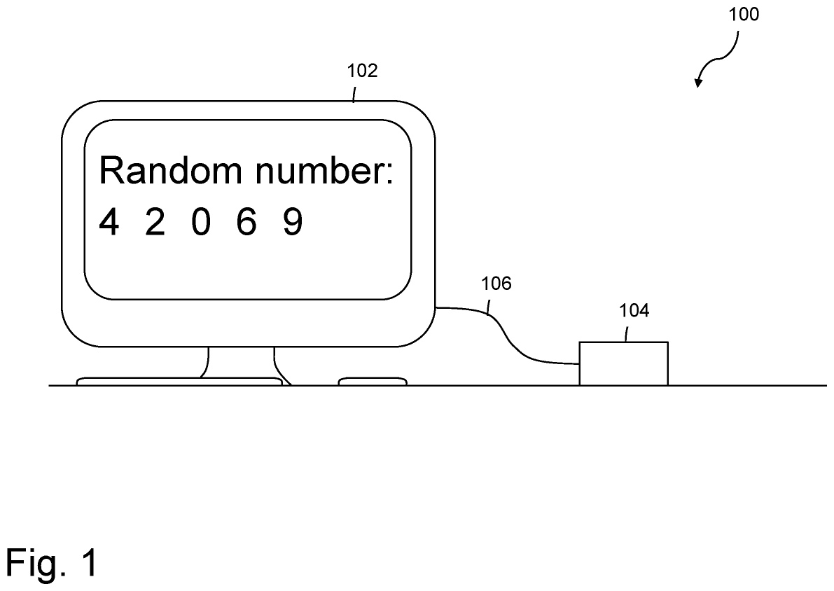

FIG. 1 shows an example of a system 100 for generating one or more random numbers, in accordance with an embodiment. As depicted, the system 100 has a computer 102, a circuit 104 and a communication link 106 communicatively coupling the computer 102 to the circuit 104. As will be described in further detail below, the circuit 104 is configured to generate an analog random signal from a quantum origin. The analog random signal is then amplified only within an audio frequency range, with frequencies below 20 kHz. As such, when the amplified analog random signal is communicated from the circuit 104 to the computer 102 via the communication link 106, the computer 102 can, via its audio processing hardware such as an audio analog-to-digital converter, digitize the amplified analog random signal into a digitized random signal which can be used as a basis for random number generation.

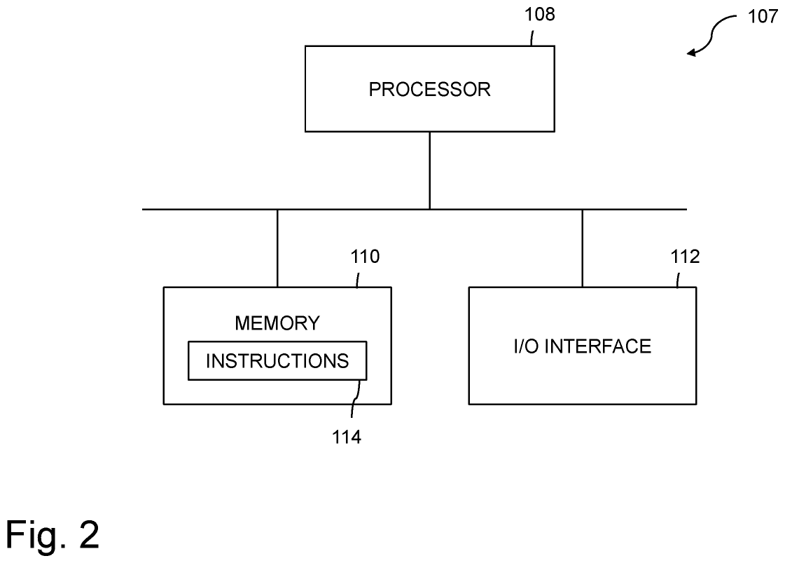

The computer 102 can be provided as a combination of hardware and software components. The hardware components can be implemented in the form of a computing device 107, an example of which is described with reference to FIG. 2. Moreover, the software components of the computer 102 can be implemented in the form of one or software applications (not shown).

Referring to FIG. 2, the computing device 107 can have a processor 108, a memory 110, and I/O interface 112. Instructions 114 for generating the random number(s) from signal(s) received from the circuit can be stored on the memory 110 and accessible by the processor 108.

The processor 108 can be, for example, a general-purpose microprocessor or microcontroller, a digital signal processing (DSP) processor, an integrated circuit, a field programmable gate array (FPGA), a reconfigurable processor, a programmable read-only memory (PROM), or any combination thereof.

The memory 110 can include a suitable combination of any type of computer-readable memory that is located either internally or externally such as, for example, random-access memory (RAM), read-only memory (ROM), compact disc read-only memory (CDROM), electro-optical memory, magneto-optical memory, erasable programmable read-only memory (EPROM), and electrically-erasable programmable read-only memory (EEPROM), Ferroelectric RAM (FRAM) or the like.

Each I/O interface 112 enables the computing device 107 to interconnect with one or more input devices, such as communication link(s), circuit(s), keyboard(s), mouse(s), and/or with one or more output devices such as monitor(s), accessible memory system(s) and/or external network(s).

Each I/O interface 112 enables the computer 102 to communicate with other components, to exchange data with other components, to access and connect to network resources, to server applications, and perform other computing applications by connecting to a network (or multiple networks) capable of carrying data including the Internet, Ethernet, plain old telephone service (POTS) line, public switch telephone network (PSTN), integrated services digital network (ISDN), digital subscriber line (DSL), coaxial cable, fiber optics, satellite, mobile, wireless (e.g., Wi-Fi, WiMAX), SS7 signaling network, fixed line, local area network, wide area network, and others, including any combination of these.

In some embodiments, the software application(s) are stored on the memory 110 and accessible by the processor 108 of the computing device 107. The computing device 107 and the software application(s) described above and herein are meant to be examples only. Other suitable embodiments of the computer 102 can also be provided, as it will be apparent to the skilled reader. For instance, the computer 102 can be provided in the form of a desktop computer, a personal computer, a laptop computer, a smart phone, an electronic tablet, or any computer having audio processing hardware.

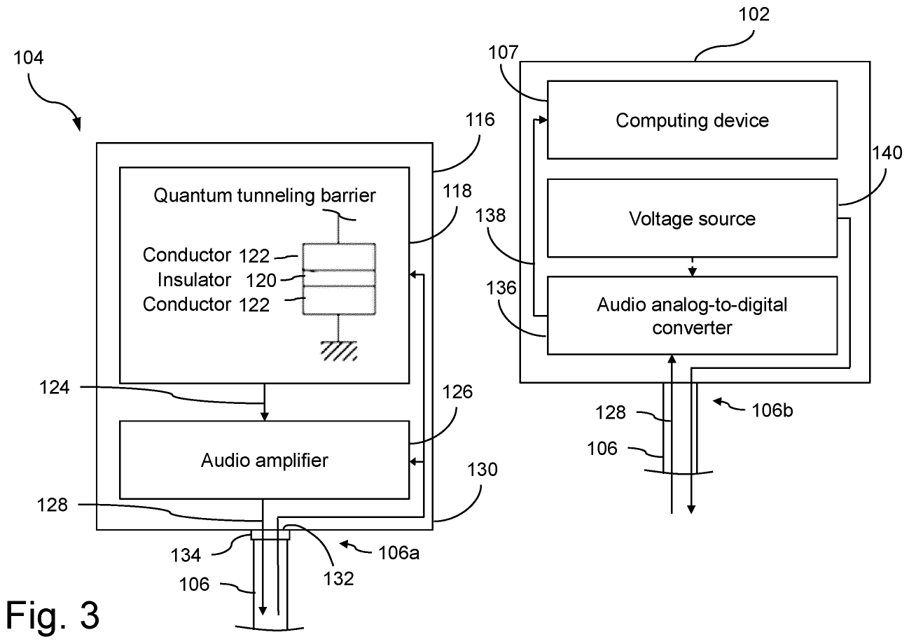

Referring now to FIG. 3, the circuit 104 has a board 116 and a quantum tunnelling barrier 118 mounted to the board 116. As shown, the quantum tunnelling barrier 118 has an insulator 120 having two exterior opposite faces each in contact with a corresponding one of two conductors 122 and allowing charges to randomly tunnel from one of the conductors 122 to the other conductor 122 across the insulator 120 to form a current of tunneled charges passing through the insulator 120. It is intended that the current of tunneled charges have an instantaneous level varying randomly due to quantum tunneling and forms an analog random signal 124. Examples of such quantum tunnelling barriers are described in International Patent Applications published under nos. WO 2015/168798 and WO 2019/136545, the contents of which are hereby incorporated by reference. It is not uncommon for such quantum tunnelling barriers to have a bandwidth of about 600 MHZ. In other words, the analog random signal the quantum tunnelling barrier 118 typically produces can carry have frequencies in the Hz range, in the kHz range, in the MHz range and in the GHz range. Some specific quantum tunnelling barriers can produce analog random signals with frequencies as low as 0.1 MHz and as high as 6,000 MHZ, depending on the embodiment. In some embodiments, the quantum tunnelling barrier 118 can be provided in the form of a chip which is soldered, bonded or otherwise connected to the board 116. In some other embodiments, the quantum tunnelling barrier 118 can be manufactured directly on the board 116. The board 116 can be a printed circuit board (PCB) in some embodiments.

The circuit 104 is provided with an audio amplifier 126 which is mounted to the board 116 and which is configured for amplifying the analog random signal 124 within an audio frequency range, thereby generating an amplified analog random signal 128. The audio frequency range across which amplification occurs generally includes frequencies between 10 Hz and 20 KHz. However, the audio frequency range across which amplification occurs, i.e., the amplification band, is broadly defined as including frequencies below 20 kHz. In some embodiments, the audio amplifier 126 is configured to amplify at least 80% of the audio frequency range, preferably at least 90% of the audio frequency range and most preferably at least 95% of the audio frequency range.

It was found that by using the audio amplifier 126, instead of using other types of amplifiers which would amplify a broader range of frequencies, the bulkiness and cost of the circuit 104 can be greatly reduced. This bulkiness and cost reduction come at the cost of a reduction in the rate at which random numbers can be generated. However, it was found that the low-cost nature of these audio amplifiers can greatly overcome the random number rate for at least some applications including, but not limited to, consumer electronic applications.

In some embodiments, the circuit 104 can have a housing 130 enclosing the quantum tunneling barrier 118 and the audio amplifier 126. As shown, the housing 130 can have a communication port 132 to which a connector 134 of the communication link 106 is removably connected during use. As such, the circuit 104 can be disconnected from the communication link 106 during storage or transportation, as desired. The type of the connector, and therefore the type of the communication link, can differ from one embodiment to another. For instance, the connector 134 can be an analog VGA connector, a DVI connector, a RCA connector, a 3-pin XLR connector, a 5-pin XLR connector, a 6.5 mm TRS connector, a jack connector and/or any other suitable audio or video connector. As discussed further below, the connector 134 can be a USB connector used in an analog mode of operation sometimes referred to as the “audio accessory mode.” In some embodiments, the communication link 106 has one end 106a being removably (or fixedly) coupled to the audio amplifier 126 or communication port 134 of the circuit 104, and another end 106b being removably (or fixedly) coupled to the computer 102.

As shown, the computer 102 has an audio analog-to-digital converter 136 which is in communication with the communication link 106. The audio analog-to-digital converter 136 can be part of the sound processing hardware of the computer 102, namely the sound card for instance. During use, the amplified analog random signal 128 received from the audio amplifier 126 of the circuit 104 via the communication link 106 is converted into a digitized random signal 138 by the audio analog-to-digital converter 136. As illustrated in this example, the digitized random signal 138 can be sent to the computing device 107 where random numbers can be outputted on the basis of the digitized random signal 138. In some embodiments, the digitized random signal 138 incorporates random bit samples used as a basis for random number generation. For instance, at a given moment in time, the audio analog-to-digital converter 136 may sample the amplified analog signal 128 to have a value worth 5 out of a maximum value of 2⁴−1=15, and then provide the random bit sample 0101.

The associated random number may thus be 5 for that bit sample. By juxtaposing a significant number of such bit samples, a string of random numbers can be generated in a relatively short amount of time in this manner. By amplifying frequencies within the audio frequency range, it is noted that the rate of generation of random bit samples may be lower compared to what could be produced by amplifying greater frequencies. However, it is anticipated that using the audio analog-to-digital converter 136 of a standard personal computer, which operates generally at about 20 kS/s (kilo samples per second), the rate of generation of random bit samples can achieve at least 10 kb/s in some embodiments.

In this embodiment, the computer 102 is shown with a voltage source 140. As shown, the voltage source 140 is used in this example to power the circuit 104 via the communication link 106. More specifically, the voltage source 140 can apply a bias voltage to the quantum tunnelling barrier 118 via the communication link 106. In some embodiments, the bias voltage outputted by the voltage source 140 can be modulated in a testing mode to confirm whether the quantum tunnelling barrier 118 works as expected. Moreover, the voltage source 140 can power the audio amplifier 126 via the communication link 106 as well. It is understood that although the voltage source 140 is shown to be separate from the computer device 107 in this embodiment, in some other embodiments, the voltage source 140 can be part of the computer device or even part of the audio analog-to-digital converter 136. For instance, the voltage source 140 can be part of a sound card of the computer 102, with the bias voltage corresponding to an audio output signal of the sound card. It is intended that with such a configuration, no voltage source is needed directly on the board 116 as power is drawn from the computer 102 via the communication link 106.

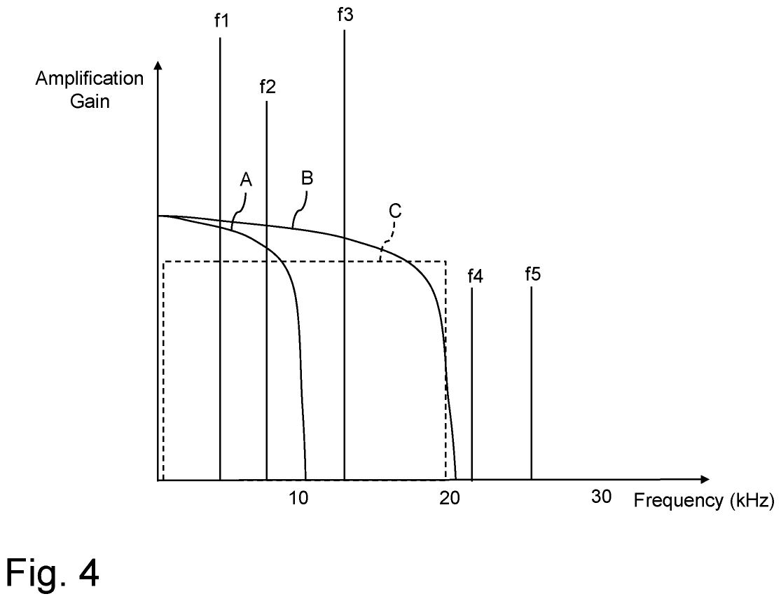

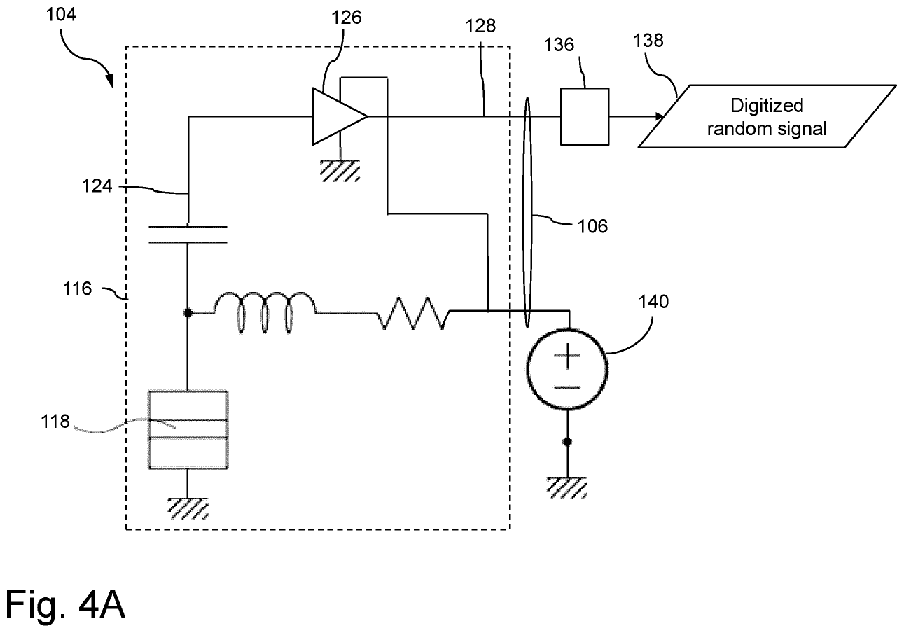

FIG. 4 shows exemplary amplification bands A and B of the audio amplifier of the circuit discussed above. As shown, the dashed rectangle C bounds what is generally accepted as the conventional audio frequency range, extending from 10 Hz to 20 kHz. Of the two amplification bands A and B that are depicted in this figure, the amplification band A extends from 0 Hz to about 10 KHz, and the amplification band B extends from 0 Hz to about 20 KHz. As such, frequencies f1 and f2 may be amplified by the amplification band A whereas frequencies f1, f2 and f2 may be amplified by the amplification band B. As shown, frequencies above the audio frequency range, such as frequencies f4 and f5, are not amplified by either one of the amplification bands A and B. It is understood that the amplification bands and spectral content of the analog random signal (e.g., f1, f2, f3, f4 and f5) have been simplified for ease of understanding, and that any other amplification band shape or range within the audio frequency range can be used depending on the embodiment.

As best shown in FIG. 4A, the circuit 104 includes the quantum tunnelling barrier 118, the audio amplifier 126, and capacitor(s), inductor(s), and/or resistor(s), depending on the embodiment. As depicted in this specific embodiment, the quantum tunnelling barrier 118 has one of the two conductors which is grounded, and the other one of the two conductors which is biased via the voltage source 140. The voltage source 140 in this embodiment is external to the circuit 104 as it is part of the computer. However, the communication link 106 is used to receive a voltage to bias the quantum tunnelling barrier 118 and also to communicate the amplified analog random signal to the computer. In this way, the communication link 106 is a bidirectional use.

Different types of audio amplifiers can be used. For instance, typical audio amplifiers are generally categorized in classes including, but not limited to, classes A, B, AB and C. For instance, class A audio amplifiers are the most common type of audio amplifier topology as they use just one output switching transistor (e.g., bipolar transistor, field-effect transistor (FET), insulated-gate bipolar transistor (IGBT)) within their amplifier design. Class B audio amplifiers can use two complimentary transistors either bipolar of FET for each half of the waveform with its output stage configured in a “push-pull” type arrangement, so that each transistor device amplifies only half of the output waveform. Class AB audio amplifiers are a variation of a class B audio amplifiers as described above, except that both amplifiers are allowed to conduct at the same time around the waveforms crossover point eliminating the crossover distortion problems of the previous class B audio amplifiers. Class C audio amplifiers are heavily biased so that the output current is zero for more than one half of an input sinusoidal signal cycle with the transistor idling at its cut-off point. In other words, the conduction angle for the transistor is significantly less than 180 degrees, and is generally around the 90-degree area. In some embodiments, the audio amplifier is a class A audio amplifier, a class B audio amplifier, a class AB audio amplifier, a class C audio amplifier or any other satisfactory class of audio amplifier. In some embodiments, the audio amplifier is provided in the form of one or more operation amplifiers (op amps).

The two functions of the communication link 106 help reduce the number of components required directly on the board 116 of the circuit 104. As shown, in this example, the voltage source 140 can be external, separate from the circuit 140 and still be able to power the audio amplifier 126 and bias the quantum tunnelling barrier 118 using power originating from the computer thanks to the communication link 106. Examples of such communication links can include analog cables, USB cables, Lightning™ cables, and the like. The communication link 106 can have a connector connectable to a corresponding connector of the external computer. In embodiments where the communication link is not a dedicated analog communication link, the connector can be a USB connector used in the audio accessory mode. The USB connector can be a USB type-A connector, a USB type-B connector, a USB type-C connector, a USB 3.0 connector, or any USB connector allowing an audio accessory mode or equivalent analog mode of use.

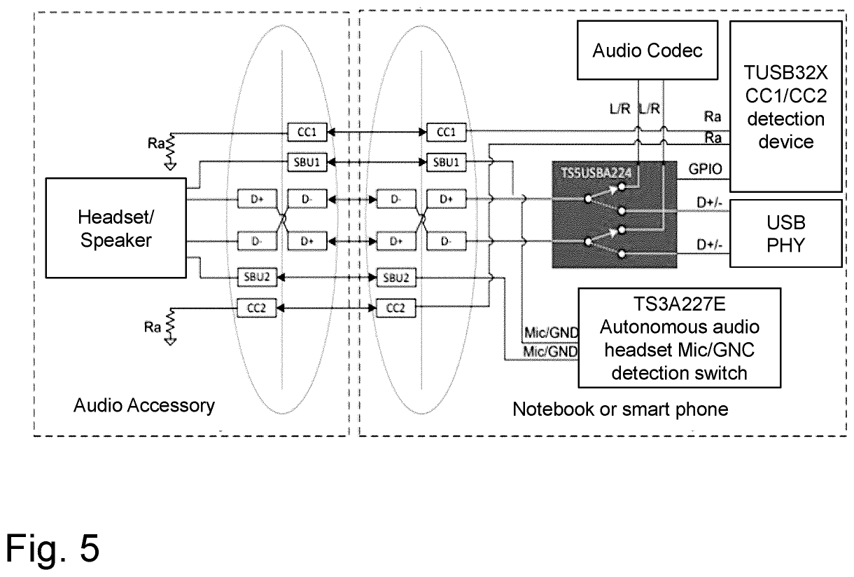

FIG. 5 shows an example of a pin diagram of a standard USB connector, in accordance with an embodiment. As shown, the USB cable can be used in an audio accessory mode. The audio accessory mode is generally supported by USB type-C connectors and other USB connectors. In the audio accessory mode, all digital circuits are disconnected from the connector, and certain pins become reassigned for analog outputs or inputs. The audio accessory mode is entered when both CC pins are shorted to the ground. In this situation, the D− and D+ pins become audio output left L and right R, respectively. The SBU pins become a microphone pin MIC, and the analog ground AGND. The analog ground AGND becomes a return path for both outputs and the microphone. The audio accessory mode allows concurrent biasing of the quantum tunnelling barrier, and powering of the audio amplifier, exposing the analog audio interface through the VBUS and GND pins. These pins may provide 5 V and 500 mA in some embodiments. Accordingly, the audio amplifier may be selected based on its voltage and current consumption. The audio accessory mode is not new to USB type-C connectors, but is also available in some other, prior generation USB connectors. These other USB connectors may be used in conjunction of the communication link described above in some embodiments.

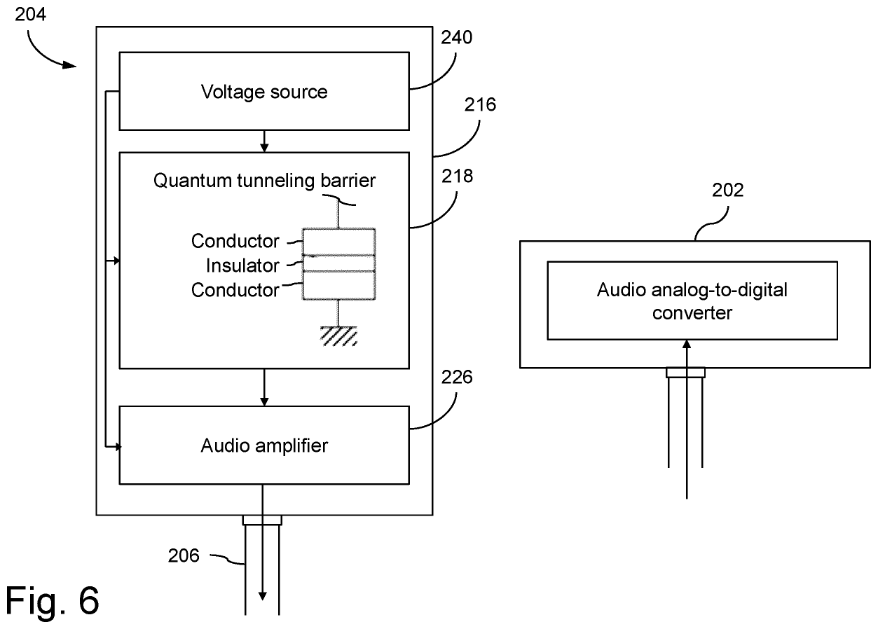

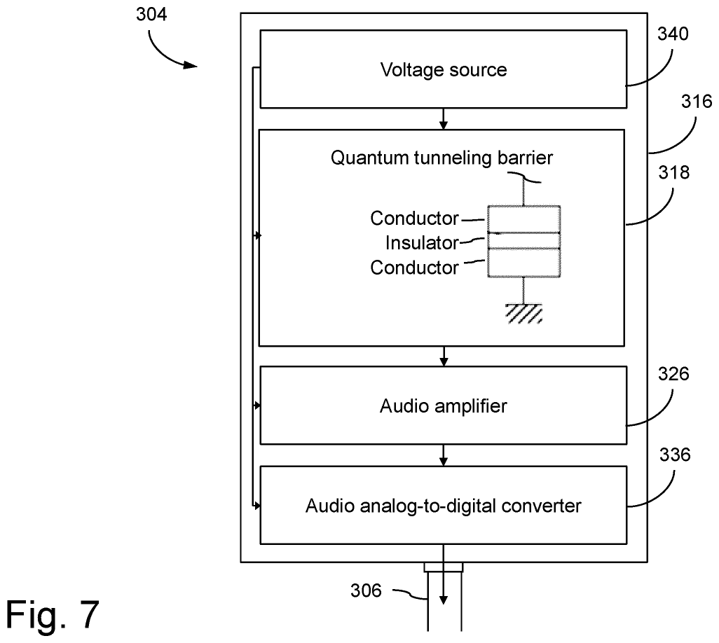

Other embodiments of the circuit are also intended. FIG. 6 shows another example of a circuit 204 having a quantum tunnelling barrier 218, an audio amplifier 226 and a voltage source 240 all mounted directly to a board 216. In this embodiment, a communication link 206 is used to communicate the amplified analog signal to the audio analog-to-digital converter of the computer 202. In this embodiment, the voltage source 240 is configured for both applying a bias voltage between the two conductors of the quantum tunneling barrier and for powering the audio amplifier. In these embodiments, voltage or electrical power is not drawn from the computer 202 but is rather generated on-board when necessary. An electrical switch can be mounted to the board to selectively activate or deactivate the voltage source 240 when desired. In some other embodiments, such as the one shown in FIG. 7, a circuit 304 has a quantum tunnelling barrier 318, an audio amplifier 326, an audio analog-to-digital converter 336 and a voltage source 340. All these components can be mounted directly to a board 316. In this embodiment, the audio analog-to-digital converter 336 is configured for converting the amplified analog random signal into a digitized random signal directly on the board 316. In some embodiments, the communication link 306 can be provided in the form of a network connection such as an Internet connection. In these embodiments, the digitized random signal can be communicated in a wired manner, or wireless manner or a combination thereof. In the embodiments shown in FIGS. 6 and 7, it is acknowledged that the bulkiness of the circuits 204 and 304 may be increased, however the circuits 204 and 304 still benefit from the use of the audio amplifiers 226 and 326 to lower costs. In these embodiments, the circuits 204 and 304 may have a switch to turn on (or turn off) the voltage source and thereby bias the quantum tunnelling barrier and power the audio amplifier and the audio digital-to-converter, or other components that the circuits may have.

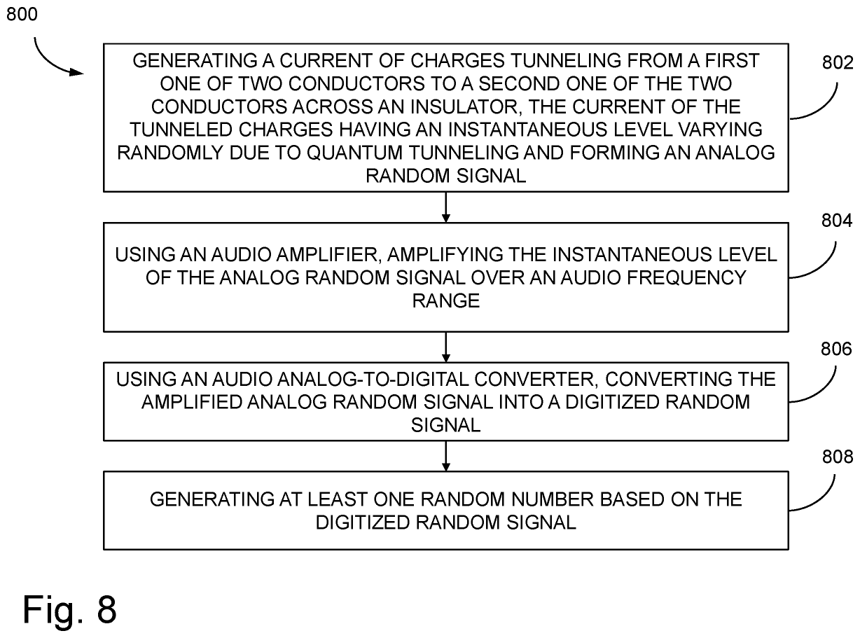

FIG. 8 is a flow chart of a method 800 of generating random numbers. The method 800 is described with reference to the components described above, and can be performed by any one of the circuits described with reference to FIGS. 1, 3, 6 and 7. At step 802, a current of charges is generated by tunneling from a first one of two conductors to a second one of the two conductors across an insulator. The current of the tunneled charges has an instantaneous level varying randomly due to quantum tunneling and forms an analog random signal. At step 804, using an audio amplifier, the instantaneous level of the analog random signal is amplified over an audio frequency range. The audio frequency range includes frequencies below 20 kHz as described above. The amplification gain can be constant or varying across the selected audio frequency range. At step 806, the amplified analog random signal is converted into a digitized random signal using an audio analog-to-digital converter. At step 808, at least one random number is generated based the digitized random signal. As discussed above, in some embodiments, the amplified analog random signal is communicated from the audio amplifier to the audio analog-to-digital converter using a communication link. In these embodiments, a bias voltage can be applied across the two conductors via the communication link. The method can also have a step of powering the audio amplifier via the communication link.

It is known that the shot noise (i.e., noise of quantum origin) generated by electrons crossing the quantum tunnelling barrier via quantum tunnelling are used to generate random bits or numbers. The higher the bandwidth the more numbers per second can be generated, so it is usually desirable to work at high frequency. As described above, for certain applications, however, a lower bit rate is enough and one might want to digitize only the low frequency noise generated by the quantum tunnelling barrier. One may do so by leveraging low cost and mass-produced audio amplifiers operating in the audio frequency range. It is known that shot noise is frequency independent up to a cut-off frequency given by the RC time of the quantum tunnelling barrier. Thus, in principle, there may not be any limit for the shot noise at low frequency. However, in some embodiments, the conductors of the quantum tunnelling barrier can create noise that is inversely proportional to the frequency f (or 1/f noise, also called “flicker noise”) of the noise. The flicker noise is negligible and can be ignored at high frequencies, but it can become predominant at low frequencies. The origin of the flicker noise lies in defects that move within the quantum tunnelling barrier, thus creating random variations of the barrier's resistance. The flicker noise does not affect the voltage noise at equilibrium but can generate extra noise such as [symbol] δV² [symbol] = [symbol] δR² [symbol] I² in the presence of a bias current I, with [symbol] δR² [symbol] denoting the variance of resistance fluctuations. For some low quality Nb/Al oxide/Nb quantum tunnelling barriers operated at room temperature, the shot noise may be completely dominated by the flicker noise (1/f noise) up to 600 kHz, in some embodiments. However, this may not be the case for other types of quantum tunnelling barriers. It is known that the spectral density S_{V} of the flicker noise can be given by:

$${S}_{V} = \frac{α {V}^{2}}{Af} , \qquad ( 1 )$$

with α denoting the Hooge parameter characterizing the purity of the barrier. Generally, the larger the Hooge parameter is the larger the flicker noise. Some techniques may be used to reduce the impacts of the flicker noise in some quantum tunneling barriers. For instance, in some embodiments, the quantum tunnelling barrier is manufactured using state-of-the-art manufacturing techniques aiming at reducing the number of defects present or moving within the two conductors. In these embodiments, flicker noise may be reduced or even removed. In some other embodiments, other techniques may be used to limit the flicker noise as much as possible. For instance, as the flicker noise decays like 1/f, the quantum tunnelling barrier and the audio amplifier are operated at higher frequencies of the audio frequency range. For instance, operation of these components can be limited to a range extending between about 15 kHz to 20 kHz, preferably between about 17 kHz and 20 kHz, and most preferably between about 18 kHz and 20 KHz. It is noted that flicker noise can also grow as the square of the bias voltage/current. Accordingly, in some embodiments, the quantum tunnelling barrier and/or the audio amplifier may be operated at low current, or even at equilibrium, i.e., without any bias, to reduce any adverse effects pertaining to flicker noise. The flicker noise may also decay as the inverse of the area of the quantum tunnelling barrier. Accordingly, in some embodiments, the quantum tunnelling barrier can be sized and shaped to have a larger area thereby reducing the flicker noise. In these embodiments, to keep the resistance constant, the thickness of the quantum tunnelling barrier can be increased provided that it does not deteriorate the Hooge parameter a. It is also encompassed that clean junctions, i.e., quantum tunnelling barriers having a very low defect density, can be preferred. For instance, epitaxial or annealed junctions can be preferably used. In some embodiments, the quantum tunnelling barrier is used in a way that the proportion of flicker noise versus shot noise is calculated. In these embodiments, the calculated proportion is used as an input to post-processing aiming at removing the components associated with the flicker noise. Operating the quantum tunnelling barrier at lower temperatures may also reduce the flicker noise. As discussed above, it is intended that the flicker noise can be challenging in situations where manufacturing is not optimal. Accordingly, in embodiments where the quantum tunnelling barriers are manufacturing to reduce defects and increase purity, the flicker noise may be neglected.

As can be understood, the examples described above and illustrated are intended to be exemplary only. For instance, in some embodiments, the audio amplifier is provided in the form of one or more conventional operational amplifiers (op amps). In these embodiments, the op amp(s) can be used in conjunction with a pass filter which is configured to filter out frequencies above 20 kHz, preferably above 15 kHz and most preferably above 10 kHz, for instance. The pass filter can also be configured to filter out frequencies below 1 kHz, preferably below 500 Hz and most preferably below 100 Hz, depending on the embodiment. In some embodiments, the circuit can be a part of the computer, with the communication link running inside the computer, between the audio amplifier of the circuit and the audio analog-to-digital converter or other sound processing hardware that the computer may have. In these latter embodiments, the housing of the circuit can be omitted. The scope is indicated by the appended claims.

What is claimed is:

1. A system for generating at least one random number, the system comprising:
a circuit having a board, a quantum tunnelling barrier mounted to the board, the quantum tunnelling barrier having an insulator having two exterior opposite faces each in contact with a corresponding one of two conductors and allowing charges to randomly tunnel from one of the conductors to the other conductor across the insulator to form a current of tunneled charges passing through the insulator, the current of tunneled charges having an instantaneous level varying randomly due to quantum tunneling and forming an analog random signal, an audio amplifier mounted to the board and configured for amplifying the analog random signal within an audio frequency range, the audio frequency range including frequencies below 20 kHz, thereby generating an amplified analog random signal;
a communication link communicatively coupled to the audio amplifier; and
a computer being having a processor, a computer-readable memory and audio analog-to-digital converter in communication with the communication link, the computer-readable memory having stored thereon instructions that when executed by the processor perform the steps of:
the audio analog-to-digital converter converting the amplified analog random signal into a digitized random signal; and
the processor generating at least one random number based on the digitized random signal.

2. The system of claim 1 wherein the computer has a voltage source applying a bias voltage between the two conductors of the quantum tunneling barrier via the communication link.

3. The system of claim 1 wherein the computer has a voltage source powering the audio amplifier via the communication link.

4. The system of claim 1 wherein the communication link has a connector connectable to a corresponding connector of the external computer, the connector being a USB-C connector.

5. The system of claim 4 wherein the USB-C connector is operated in an audio accessory mode.

6. The system of claim 1 wherein the board of the circuit is a printed circuit board.

7. The system of claim 1 further comprising a housing enclosing the circuit and the audio amplifier, the housing having a communication port to which the communication link is removably connected.

8. The system of claim 1 wherein the audio analog-to-digital converter is part of a sound card of the computer.

9. The system of claim 1 wherein the circuit is part of the computer.

10. A circuit for communicating an analog random signal, the circuit comprising:
a board;
a quantum tunnelling barrier mounted to the board, the quantum tunnelling barrier having an insulator having two exterior opposite faces each in contact with a corresponding one of two conductors and allowing charges to randomly tunnel from one of the conductors to the other conductor across the insulator to form a current of tunneled charges passing through the insulator, the current of tunneled charges having an instantaneous level varying randomly due to quantum tunneling and forming an analog random signal;
an audio amplifier mounted to the board and configured for amplifying the instantaneous level of the analog random signal within an audio frequency range and generating an amplified analog random signal, the audio frequency range including frequencies below 20 kHz; and
a communication link communicatively coupled to the audio amplifier and connectable to an external computer for communicating the amplified analog random signal thereto.

11. The circuit of claim 10 wherein the audio amplifier is configured to amplify at least 80% of the audio frequency range, preferably at least 90% of the audio frequency range and most preferably at least 95% of the audio frequency range.

12. The circuit of claim 10 further comprising a voltage source mounted to the board, the voltage source being configured for applying a bias voltage between the two conductors of the quantum tunneling barrier and for powering the audio amplifier.

13. The circuit of claim 10 further comprising an audio analog-to-digital converter mounted to the board, the audio analog-to-digital converter being configured for converting the amplified analog random signal into a digitized random signal.

14. The circuit of claim 10 wherein the communication link has a connector connectable to a corresponding connector of the external computer, the connector being a USB-C connector.

15. The circuit of claim 14 wherein the USB-C connector is operated in an audio accessory mode.

16. The circuit of claim 10 wherein the board is a printed circuit board.

17. A method of generating at least one random number, the method comprising:
generating a current of charges tunneling from a first one of two conductors to a second one of the two conductors across an insulator, the current of the tunneled charges having an instantaneous level varying randomly due to quantum tunneling and forming an analog random signal;
using an audio amplifier, amplifying the instantaneous level of the analog random signal over an audio frequency range, the audio frequency range including frequencies below 20 kHz;
using an audio analog-to-digital converter, converting the amplified analog random signal into a digitized random signal; and
generating at least one random number based the digitized random signal.

18. The method of claim 17 further comprising a communication link communicating said amplified analog random signal from the audio amplifier to the audio analog-to-digital converter.

19. The method of claim 18 further comprising applying a bias voltage across the two conductors via the communication link.

20. The method of claim 18 further comprising powering the audio amplifier via the communication link.
